(19) United States
(12) Patent Application Publication
(10) Pub. No.: US 2021/0242849 A1
(43) Pub. Date: Aug. 5, 2021

(54) METHOD FOR MANUFACTURING AN ELECTRO-ACOUSTIC RESONATOR AND ELECTRO-ACOUSTIC RESONATOR DEVICE

(71) Applicant: RF360 EUROPE GMBH, Munchen (DE)

(72) Inventor: Joachim KLETT, Munich (DE)

(21) Appl. No.: 17/278,643

(22) PCT Filed: Sep. 5, 2019
(86) PCT No.: PCT/EP2019/073713

§ 371 Date: Mar. 22, 2021

(30) Foreign Application Priority Data
Oct. 26, 2018 (DE) 10 2018 126 804.1

(51) Int. Cl. H03H 3/02; H03H 9/02; H03H 9/13; H03H 9/17; H01L 41/047; H01L 41/08; H01L 41/29; H01L 41/319; C25D 7/00; C25D 5/02; C25D 3/50; C25D 3/12

(52) U.S. Cl. CPC H03H 3/02; H03H 2003/025; H03H 9/13; H03H 9/174; H03H 9/175; H03H 9/176; H01L 41/0477; H01L 41/0815; H01L 41/29; H01L 41/319; C25D 7/00; C25D 5/02; C25D 3/50; C25D 3/12; H03H 2003/023; H03H 9/02031

(57) ABSTRACT

A seed layer (210) of a noble metal is formed by electrochemical deposition on a metal electrode (111) disposed on a dielectric layer (110,310). The noble metal seed layer allows the deposition of a highly textured piezoelectric layer (320) on the metal electrode.

### TECHNICAL FIELD

The present disclosure relates to electro-acoustic resonators. Specifically, the present disclosure relates to a method for manufacturing an electro-acoustic resonator that includes the forming of a metal electrode on a dielectric layer and the forming of a piezoelectric layer on the metal electrode.

### BACKGROUND

Electro-acoustic resonators are widely used in electronics to form RF filters and other RF devices. One type of electro-acoustic resonator is a bulk acoustic wave (BAW) resonator that comprises a piezoelectric layer sandwiched between a pair of bottom and top metal electrodes. By the application of an electrical RF signal to the electrodes, a resonating acoustic wave is generated within the piezoelectric layer. The interaction between the electrical RF signal and the resonating acoustic wave performs a frequency selective filtering function on the electrical signal. The crystallographic alignment of the piezoelectric layer becomes more important for future RF communication filters to meet the enhanced performance requirements. An increased crystallinity causes an increased electro-acoustic coupling of the piezoelectric layer.

It is an object of the present disclosure to provide a method for manufacturing an electro-acoustic resonator that exhibits enhanced performance.

It is another object of the present disclosure to provide a method for manufacturing an electro-acoustic resonator with a piezoelectric film layer that exhibits increased crystallinity.

It is yet another object of the present disclosure to provide an electro-acoustic resonator device with enhanced performance.

It is yet another object of the present disclosure to provide an electro-acoustic resonator with a piezoelectric layer of enhanced crystallinity.

### SUMMARY

One or more of the above-mentioned objects are achieved by a method for manufacturing an electro-acoustic resonator comprising the features of present claim 1.

According to the method, a metal electrode is formed on a workpiece having a dielectric top layer. A layer of a noble metal is formed on the metal electrode employing an electrochemical deposition process. This allows a selective self-limiting formation of a thin seed layer of a noble metal on the metal electrode. No noble metal layer is formed on the surface of the dielectric layer. The electrochemical process requires no structuring of the deposited noble metal layer which may be difficult due to its noble nature. Also, no lithography steps are required at this point.

The electrochemical forming of the noble metal layer on the bottom electrode layer uses a solution that contains a salt of a noble metal. The forming of the noble metal layer occurs in a self-limited manner just by immersing the workpiece including the bottom metal electrode on the dielectric layer into the noble metal salt solution.

Then, a piezoelectric layer is formed on the metal electrode covered with the noble metal layer wherein the noble nature of the seed layer the orientation of the to be deposited piezoelectric layer. Preferably, the piezoelectric layer is formed directly on the noble metal layer. The piezoelectric layer is highly textured and exhibits enhanced crystallinity so that it achieves good piezoelectric properties and increased electro-acoustic coupling. As a result, a RF filter including a BAW resonator will have a higher quality factor, steeper skirts and better suppression in the stop band.

The immersing of the workpiece into the noble metal salt solution performs an electrochemical plating process that grows a layer of the noble metal on the metal electrode, wherein the more noble metal dissolved in the solution deposits on the electrode and the less noble metal from the electrode goes into solution. The electrochemical redox process occurs at the surface of the metal electrode including a sacrificial reaction by the electrode material and a deposition reaction by the dissolved noble metal material. This process stops when the electrode material cannot diffuse any more through the deposited noble metal layer to go into solution so that the process is self-limiting.

The dielectric layer may be an oxide such as a silicon oxide or silicon dioxide so that the surface of the dielectric layer is in an oxidized state that blocks an electrochemical reaction. No electrochemical deposition of the noble metal will occur on the dielectric layer.

The workpiece that provides the dielectric layer may be processed to include a Bragg mirror layer stack on which the resonator layer sandwich is formed. The Bragg mirror prevents the acoustic waves from leaking from the piezoelectric layer and propagating into the substrate in that it reflects the waves back into the piezoelectric layer. Such a BAW structure that includes a solid reflection arrangement such as a Bragg mirror layer stack is called solidly mounted resonator (SMR). Alternatively, the resonator may exhibit a cavity beneath or opposite the acoustically active region to prevent the acoustic wave from leaking out of the piezoelectric layer. A resonator using an air cavity is called film bulk acoustic resonator or free-standing acoustic resonator (FBAR).

The metal electrode may comprise metal materials such as tungsten, molybdenum, titanium, aluminum or copper. Specifically, materials such as tungsten and molybdenum are acoustically relatively hard materials useful for BAW resonators of enhanced performance. An aluminum layer may include a certain amount of copper to make it acoustically harder. The copper may diffuse through the aluminum during a thermal process forming grains of an intermetallic phase of aluminum and copper (Al₂Cu).

The metal electrode may be structured before immersing the workpiece into the solution. For example, the metal electrode is structured such that regions of the top side of the substrate on which the metal electrode is formed are free of the metal electrode. Structuring may be done by etching with help of a mask or by a lift of process.

The noble metal to be electrochemically deposited on the bottom electrode may comprise platinum or palladium. Also, ruthenium or nickel are useful. Salts of these metals are dissolved within the electrochemical bath to go into solution and provide a source of the metals for the electrochemical deposition process. Salts to be used are as follows:

sodium hexachloroplatinate (II) or Na₂PtCl₆;
potassium hexachloroplatinate (II) or K₂PtCl₆;
sodium tetrachloropalladate (II) or Na₂PdCl₄;
potassium tetrachloropalladate (II) or K₂PdCl₄;
potassium hexachloropalladate (IV) or K₂PdCl₆;
ruthenium (III) chloride hydrate or RuCl₃.3H₂O;
nickel (II) chloride; and
nickel (II) sulfate.

The electrochemical bath may also contain a reducing agent that accelerates or assists the deposition redox reaction. The reducing agent may consist of hydrazine (N₂H₄). Another reducing agent may also be useful.

Any of these metals such as platinum, palladium, ruthenium and nickel are known as good seed layers for the further deposition of a piezoelectric layer. By way of theory, it is assumed that these metals have a lattice structure that is similar to the lattice structure of a piezoelectric layer such as a layer of aluminum nitride or aluminum scandium nitride. Furthermore, these metals may have a catalytic function so that the dissociation of nitrogen during the deposition of aluminum nitride or aluminum scandium nitride is facilitated.

The noble metal layer deposited on the bottom metal electrode with the above-described electrochemical plating process forms a seed layer for the deposition of a piezoelectric layer such as aluminum nitride (AlN) or aluminum scandium nitride (AlScN). The use of a scandium portion in the aluminum nitride increases the coupling of the piezoelectric layer, however, makes the deposition of aluminum scandium nitride more difficult. The forming of the noble metal seed layer is specifically useful for a higher amount of scandium in the piezoelectric aluminum scandium nitride layer. For example, the scandium content in the aluminum scandium nitride layer may be more than 5 at-%. The described process may be particularly useful with a scandium portion of more than 10 at-% of scandium. More specifically, the aluminum scandium nitride layer contains between 10 at-% and up to 40 at-% of scandium.

The process according to the present disclosure may be applied to solidly mounted BAW resonators (SMR BAW), wherein a Bragg mirror layer stack serves to confine the acoustic energy within the piezoelectric layer. The process according to the present disclosure is also applicable for film bulk acoustic resonators (FBAR) that have a cavity opposite the acoustically active region to prevent the acoustic energy from escaping from the piezoelectric layer. With SMR or FBAR type resonators, the top surface of the substrate includes a dielectric layer such as a silicon dioxide layer.

According to a specific embodiment, the manufacturing of an electro-acoustic resonator may comprise, in more detail, the providing of a substrate including a Bragg mirror layer stack that includes a top layer of silicon dioxide or a thin substrate film layer that has a top layer of silicon dioxide. A metal layer is formed on the silicon dioxide to form a bottom electrode. The metal layer may comprise one of tungsten or molybdenum to provide an acoustically stiff electrode layer. The tungsten or molybdenum layer may be deposited and structured to form the required size of the bottom electrode. A platinum salt solution or a palladium salt solution is applied to the substrate in that the substrate, including the Bragg layer stack or the silicon dioxide film layer including the bottom electrode, is immersed into the salt solution. Then, an aluminum scandium nitride layer is deposited on the platinum or palladium layer that was formed on the electrode layer. The aluminum scandium nitride layer may include at least 10 at-% of scandium. The process is continued to complete the forming of a SMR or FBAR resonator in that a top electrode layer is formed on the piezoelectric aluminum scandium nitride layer. The process allows a selective deposition of platinum or palladium on the bottom electrode layer, avoiding lithography and structuring steps for these seed layers. The crystallinity of the piezoelectric aluminum scandium nitride layer is increased by the platinum or palladium seed layer.

One or more of the above-mentioned objects are also achieved by an electro-acoustic resonator device according to the features of present claim 14.

An electro-acoustic resonator device manufactured according to the above-mentioned process comprises a dielectric substrate layer. A bottom electrode is disposed on the dielectric substrate. A seed layer of a noble metal is disposed on the electrode. A layer of a piezoelectric material is disposed on the noble metal seed layer. The substrate may be silicon dioxide and the bottom electrode may be made of molybdenum or tungsten disposed on the silicon dioxide substrate. The seed layer of a noble metal may be made of platinum, palladium, ruthenium or nickel disposed on the bottom electrode layer. A layer of aluminum scandium nitride comprising at least 10 at-% of scandium is disposed on the seed layer.

The electrode is particularly disposed on a top side of the dielectric substrate. Preferably, regions of the top side of the substrate are free of the electrode, i.e. are not covered by the electrode. Particularly preferably, regions of the top side of the substrate are free of the layer of the noble metal. For example, the regions of the top side of the substrate being free of the layer of the noble metal are also free of the electrode.

The layer of the noble metal preferably fully covers all sides of the electrode not facing the substrate. Thus, the layer of the noble metal fully covers the side of the electrode facing away from the substrate and side surfaces of the electrode running transversely to the top side of the electrode. In this way the electrode may be protected against oxidation.

It is to be understood that both the foregoing general description and the following detailed description are merely exemplary, and are intended to provide an overview or framework to understand the nature and character of the claims. The accompanying drawings are included to provide a further understanding and are incorporated in, and constitute a part of, this description. The drawings illustrate one or more embodiments, and together with the description serve to explain principles and operation of the various embodiments. The same elements in different figures of the drawings are denoted by the same reference signs.

### BRIEF DESCRIPTION OF THE DRAWINGS

In the drawings:

FIG. 1 shows a cross-section of a workpiece;

FIG. 2 shows the workpiece after the electrochemical forming of a noble metal seed layer on the bottom electrode layer;

FIG. 3 shows a cross-section of a BAW resonator of the SMR type; and

FIG. 4 shows a cross-section of a BAW resonator of the FBAR type.

### DETAILED DESCRIPTION OF EMBODIMENTS

The present disclosure will now be described more fully hereinafter with reference to the accompanying drawings showing embodiments of the disclosure. The disclosure may, however, be embodied in many different forms and should not be construed as limited to the embodiments set forth herein. Rather, these embodiments are provided so that the disclosure will fully convey the scope of the disclosure to those skilled in the art. The drawings are not necessarily drawn to scale but are configured to clearly illustrate the disclosure.

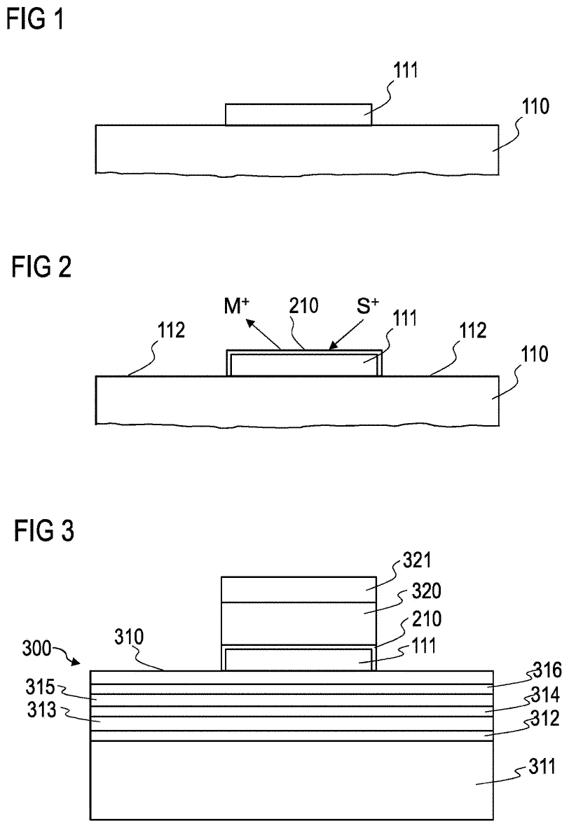

Turning now to FIG. 1, a workpiece is provided of which the topmost portion is depicted. Layer 110 is the top layer of the workpiece comprising a dielectric layer. Dielectric layer 110 may be a silicon oxide layer such as silicon dioxide. Other dielectric oxide layers are also useful. Layer 110 may be the top layer of a Bragg mirror structure. An electrode layer 111 is formed on the dielectric layer 110. Electrode 111 forms the bottom electrode of a BAW resonator. Electrode 111 may be made of tungsten or molybdenum. Alternatively, electrode 111 may be made of titanium, aluminum or a composition of aluminum and copper. Electrode 111 is grown on the surface of dielectric 110 and structured to achieve suitable size and shape of the bottom electrode.

Turning now to FIG. 2, the workpiece of FIG. 1 is immersed into a solution of a noble metal salt such as Na₂PtCl₆ or Na₂PdCl₄. Other metal salts useful to provide the solution are K₂PtCl₆, K₂PdCl₄, K₂PdCl₆, RuCl₃.3H₂O, nickel (II) chloride, and nickel (II) sulfate. An electrochemical process takes place in which metal ions S⁺ such as ions of platinum, palladium, ruthenium or nickel deposit on the top and sidewall surface of electrode 111. At the same time, metal ions M⁺ migrate out from electrode 111 and dissolve in the electrochemical solution.

According to the electrochemical working principle, the metal ions S⁺ in the electrochemical solution are more noble than the metal ions M⁺ in the electrode 111. The metallized areas of the electrodes such as 111 are separated by dielectric areas of dielectric layer 110 such as areas 112. By immersing the workpiece with the structured electrodes into the solution containing a noble metal salt, the electrochemical displacement reaction takes place. The less noble metal from the electrode M⁺ such as tungsten, molybdenum, titanium, aluminum or copper goes into solution while the more noble metal S⁺ dissolved in the solution such as platinum, palladium, ruthenium or nickel is deposited on the electrode as a thin layer 210. No deposition will occur on the surface of the top dielectric layer 110 of the workpiece in areas 112 as these areas are dielectric and are already in an oxidized state such as silicon dioxide. The deposition of the noble metal S⁺ is self-limiting when no more of the native metal from the electrode M⁺ is exposed to the solution. The deposited seed layer 210 fully covers the surface of the original metal electrode 111. The electrochemical process in the noble metal salt solution selectively deposits the noble metal on the metal electrode so that a structuring of the noble metal layer including a photolithography step is not required.

The deposition can be accelerated or assisted by adding a reducing agent such as hydrazine, N₂H₄, to the solution. The hydrazine will facilitate the reduction of the metal of the metal electrode in that hydrazine dissociates to nitrogen N₂ providing electrons for the reduction of metal:

N₂H₄-->N₂+4H⁺+4e⁻

Turning now to FIG. 3, a cross-section of a SMR BAW resonator is shown after additional process steps. The noble metal layer 210 serves as a seed layer for the subsequent deposition of a piezoelectric layer 320 to enable a textured nucleation of the piezoelectric material. Piezoelectric layer 320 may be a crystalline, columnar layer of aluminum nitride or aluminum scandium nitride. The content of aluminum scandium nitride may be more than 5 at-%, preferably more than 10 at-%, specifically between 10 at-% and 40 at-%. It is believed that the lattice structure of the local metal seed layer 210 is similar to the lattice structure of the piezoelectric layer 320 so that it enables a good nucleation of the piezoelectric layer to achieve a highly textured layer 320. The noble metal, such as platinum or palladium, may have a catalytic effect on the dissociation of nitrogen present in the precursor gas that enables the piezoelectric layer deposition. As a result, the piezoelectric layer 320 is highly textured and highly crystalline, allowing a high electro-acoustic coupling within the resonator. Further deposited on piezoelectric layer 320 is a top electrode layer 321 that may be made of the same materials as original bottom electrode layer 111.

The SMR BAW resonator depicted in FIG. 3 comprises further a Bragg mirror layer stack 300 on which the electrode sandwich 111, 210, 320, 321 is disposed. Bragg mirror layer stack 300 is formed on a carrier substrate 311. The Bragg mirror 300 includes a sequence of acoustically hard and acoustically soft layers which may be made of, for example, tungsten and silicon dioxide. A variety of other metal and dielectric materials suitable to form a Bragg mirror are also useful. For example, layers 312, 314, 316 may be acoustically hard layers such as tungsten layers, and layers 313, 315, 310 may be acoustically soft layers such as silicon dioxide layers. Specifically, the top layer of the Bragg mirror 310 is a dielectric layer such as silicon dioxide. Bragg mirror 300 has the function to prevent the acoustic energy from escaping into the substrate. The energy is reflected back into the piezoelectric layer 320.

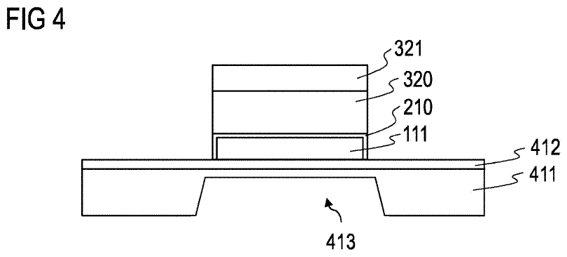

FIG. 4 shows another type of electro-acoustic resonator such as an FBAR BAW resonator. The electrode stack of layers 111, 210, 320, 321 is the same as shown for the SMR BAW type of FIG. 3. The originating workpiece 410 includes a carrier substrate 411 on which a dielectric top layer 412 is disposed on which the bottom electrode 111 is arranged. The carrier layer 111 may be a crystalline silicon, and the dielectric layer 412 may be silicon dioxide. According to the FBAR working principle, a cavity 413 is arranged opposite the electro-acoustic active area of the layer stack of top and bottom electrodes and the piezoelectric layer sandwiched therebetween. Cavity 413 is filled with ambient air that performs the function of confining the acoustic energy within piezoelectric layer 320.

In conclusion, an electrochemical deposition of a seed layer enables a deposition of a highly textured, crystalline piezoelectric layer for SMR and FBAR BAW devices. The crystallographic alignment of the piezoelectric film is enhanced. The electrochemical deposition of a noble metal material on the bottom electrode serves as a seed layer favoring higher alignment of a deposited piezoelectric material layer. The described process may be specifically useful when the piezoelectric layer is an aluminum scandium nitride layer having a scandium concentration of about more than 10 at-%.

This patent application claims the priority of the German patent application 10 2018 126 804.1, the disclosure content of which is hereby incorporated by reference.

It will be apparent to those skilled in the art that various modifications and variations can be made without departing from the spirit or scope of the disclosure as laid down in the appended claims. Since modifications, combinations, sub-combinations and variations of the disclosed embodiments incorporating the spirit and substance of the disclosure may occur to the persons skilled in the art, the disclosure should be construed to include everything within the scope of the appended claims.

1. A method for manufacturing an electro-acoustic resonator, comprising:
providing a workpiece comprising a dielectric layer;
forming a metal electrode on the dielectric layer of the workpiece;
providing a solution containing a salt of a noble metal;
immersing the workpiece having the metal electrode disposed thereon into the solution to deposit a layer of the noble metal on the metal electrode;
forming a piezoelectric layer on the metal electrode.

2. The method of claim 1, wherein immersing the workpiece into the solution comprises performing an electro-chemical plating process to deposit the layer of the noble metal on the metal electrode.

3. The method of claim 1, wherein providing a workpiece comprises providing a bragg mirror layer stack including a dielectric layer at its surface.

4. The method of claim 3, wherein the dielectric layer comprises a layer of silicon oxide or silicon dioxide.

5. The method of claim 1, wherein the metal of the metal electrode comprises at least one of tungsten, molybdenum, titanium, aluminum and copper.

6. The method of claim 1, wherein the step of forming a metal electrode comprises forming a metal electrode of a metal selected from one of tungsten, molybdenum, titanium, aluminum and a composition of aluminum and copper.

7. The method of any of claims 1, wherein the noble metal comprises at least one of platinum, palladium, ruthenium and nickel.

8. The method of claim 1, wherein the salt of the noble metal comprises at least one of
sodium hexachloroplatinate (II) or Na₂PtCl₆,
potassium hexachloroplatinate (II) or K₂PtCl₆,
sodium tetrachloropalladate (II) or Na₂PdCl₄,
potassium tetrachloropalladate (II) or K₂PdCl₄,
potassium hexachloropalladate (IV) or K₂PdCl₆,
ruthenium (III) chloride hydrate or RuCl₃.3H₂O,
nickel (II) chloride and
nickel (II) sulfate.

9. The method of claim 1, wherein the solution further contains hydrazine or another reducing agent.

10. The method of claim 1, comprising selectively depositing a layer of the noble metal on the metal electrode and not depositing a layer of the noble metal on the surface of the dielectric layer.

11. The method of claim 1, wherein forming a piezoelectric layer comprises forming an aluminum nitride layer or an aluminum scandium nitride layer on the layer of the noble metal.

12. The method of claim 1, wherein forming a piezoelectric layer comprises forming an aluminum nitride layer or an aluminum scandium nitride layer on the layer of the noble metal, wherein the aluminum scandium nitride layer comprises more than 5 at-% or more than 10 at-% of scandium or between 10 at-% and 40 at% of scandium.

13. The method of claim 1, comprising:
providing a substrate comprising one of a bragg mirror layer stack including a top layer of silicon dioxide and a substrate layer having a top layer of silicon dioxide;
forming a metal layer on the layer of silicon dioxide comprising one of tungsten and molybdenum and stucturing the metal layer to form an electrode;
then applying a platinum salt solution or a palladium salt solution to the substrate;
then forming an aluminum scandium nitride layer having a scandium contents of at least 10 at-% on the electrode layer;
forming another electrode layer on the aluminum scandium nitride layer to form another electrode.

14. The method of claim 1, wherein the piezoelectric layer is formed on the metal electrode covered with the layer of noble metal.

15. An electro-acoustic resonator device, comprising:
a dielectric substrate;
an electrode disposed on the dielectric substrate;
a layer of a noble metal disposed on the electrode;
a layer of a piezoelectric material disposed on the layer of a noble metal.

16. The electro-acoustic resonator device of claim 15, wherein
the electrode is disposed on a top side of the dielectric substrate,
the layer of noble metal fully covers a top side of the electrode facing away from the substrate and side surfaces of the electrode running transversely to the top side of the electrode,
regions of the top side of the dielectric substrate are free of the layer of a noble metal.

17. The electro-acoustic resonator device of claim 15, comprising:
a silicon dioxide substrate layer;
an electrode layer of one of molybdenum and tungsten disposed on the silicon dioxide substrate layer;
a seed layer of one of platinum and palladium disposed on the electrode layer;
a layer of aluminum scandium nitride disposed on the seed layer, the layer of aluminum scandium nitride comprising at least 10 at-% of scandium.
